(19) United States
(12) Patent Application Publication
(10) Pub. No.: US 2012/0059775 A1
(43) Pub. Date: Mar. 8, 2012

(54) ENERGY METERING SYSTEM, ENERGY METERING METHOD AND WATT HOUR METER OF SUPPORTING DYNAMIC TIME-VARYING ENERGY PRICING

(75) Inventors: Jung Hwan OH, Seoul (KR); Jae Seong Park, Daejeon (KR)

(73) Assignee: LSIS CO., LTD.

(21) Appl. No.: 13/219,546

(22) Filed: Aug. 26, 2011

(30) Foreign Application Priority Data
Sep. 3, 2010 (KR) 10-2010-0086741

(51) Int. Cl. G06Q 30/00; G01F 1/00; G06F 19/00; G01R 21/06

(52) U.S. Cl. 705/412; 702/62; 702/45

(57) ABSTRACT

The present disclosure is disclosed to record in detail and manage information on energy use history of a user under various energy pricing systems where energy prices are changed in time. To this end, an energy meter receives time-based energy price information from a remote server, and time-sequentially records a record including time information of relevant unit time for each unit time, energy price information applied to relevant unit time and energy consumption information at the relevant unit time, whereby the information on how much, when and at what price the user has used the energy can be accurately and quite obviously managed. The energy use history can be used in various fields as data for promoting reasonable energy use, and as a base for calculating energy use charge.

Pursuant to 35 U.S.C. §119 (a), this application claims the benefit of earlier filing date and right of priority to Korean Patent Application No. 10-2010-0086741, filed on Sep. 3, 2010, the contents of which are hereby incorporated by reference in their entirety.

### BACKGROUND OF THE DISCLOSURE

1. Field

Exemplary embodiments of the present disclosure may relate to an energy metering system, an energy metering method and a watt hour meter of supporting dynamic time-varying energy pricing, wherein information on energy use history of a user can be recorded in detail and managed under various energy pricing systems where energy prices are changed in time.

2. Background

Many attempts have been made recently to efficiently use limited natural resources. Concomitant with the attempts, methods have been waged to differentiate energy prices based on energy production and consumption circumstances, and a technology called smart grid or smart meter has been gaining attentions of various fields.

The smart grid is a next generation bi-directional technological framework to realize efficient power usage by constructing a new transmission network having a communication channel along with the transmission network and using this intelligent transmission network. The background idea of the smart grid is to realize efficient management of the amount of power use, swift handling of an incident, remote control of the amount of power use, distributed power generation using power generation facilities outside the control of a power company, or charging management of an electric vehicle. An essential element of the smart grid is the smart meter.

From a view point of a user toward the smart grid, the user can utilize energy at a most reasonable time zone suitable for the user by searching for the zone in response to change in energy prices.

The term “smart meter” is an electronic meter added by communication function to enable a bi-directional communication between energy suppliers and consumers, whereby energy usage can be remotely, accurately and on-time checked without a human meter reader, there is no need of human meter readers physically going to energy consumers at a regular interval, and metering cost and energy consumption can be advantageously saved.

Meantime, as energy price is changed in time along with advancement of new energy-related technologies including the smart meter and smart grid, users can positively adjust energy consumption in response to energy prices and situations.

Under these circumstances, a technique is inevitably needed for managing an energy usage history due to reasons including, but not limited to, provision of energy price information changing in time, provision of how each user uses the energy and obtainment of calculation base of energy consumption rate.

### SUMMARY OF THE DISCLOSURE

The present disclosure is disclosed to meet the aforementioned need, and therefore, it is an object of the present disclosure to provide an energy metering system, an energy metering method and a watt hour meter of supporting dynamic time-varying energy pricing, wherein information on energy use history of a user, such as how much of energy and when a user has consumed, and what energy price the user has used the energy, can be recorded in detail and managed under various dynamic time-varying energy pricing systems.

Technical subjects to be solved by the present disclosure are not restricted to the above-mentioned description, and any other technical problems not mentioned so far will be clearly appreciated from the following description by the skilled in the art.

In one general aspect of the present disclosure, there is provided an energy metering system, the system supporting dynamic time-varying energy pricing, comprising: a remote server managing the dynamic time-varying energy pricing system where energy price changes in time; a communication network connecting the remote server and an energy meter; and the energy meter measuring energy consumption flowing via the energy metering system, and receiving time-based energy price information from the communication network, wherein the energy meter extracts current time-applied energy price information from the time-based energy price information, and time-sequentially records in storage means a record including time information of relevant unit time for each unit time, the extracted energy price information and energy consumption information at relevant unit time.

In another general aspect of the present disclosure, there is provided an energy metering method, the method supporting dynamic time-varying energy pricing system, the method comprising: receiving, by an energy meter, time-based energy price information from a remote server through a communication network; measuring, by the energy meter, energy consumption and monitoring whether a pre-set unit time has elapsed; and time-sequentially recording in storage means, by the energy meter, a record including time information of relevant unit time for each unit time, energy price information applied to relevant unit time and energy consumption information at the relevant unit time.

Optionally, the energy meter measures any one of electricity, gas and water consumption.

Optionally, the unit time is any one of one minute, two minutes, three minutes, four minutes, five minutes, six minutes, ten minutes, 12 minutes, 15 minutes, 20 minutes, 30 minutes, one hour and one day.

In still another general aspect of the present disclosure, there is provided a watt hour meter, the meter supporting dynamic time-varying energy pricing system, the meter comprising: communication means receiving time-based electric price information from a remote server or a user; metering means measuring power consumption flowing through the watt hour meter; storage means recording the measured power consumption and operation information of the watt hour meter; time check means measuring a current time; and processing means processing the watt hour meter in which electric price is dynamically changed in time, wherein the processing means extracts current time-applied electric price information from time-based electric price information received from the communication means, and time-sequentially records in storage means a record including time information of relevant unit time for each unit time, the extracted electric price information and power consumption information at relevant unit time.

Optionally, the watt hour meter further includes display means capable of displaying electric price information.

Optionally, the display means displays the current time-applied electric price information at all times or intermittently.

Optionally, the display means periodically displays the current time-applied electric price information.

Optionally, the processing means displays future time-scheduled electric price information through the display means.

Optionally, the current time measured by the time check means is adjustable.

Optionally, the current time is adjustable by communication with other devices, or personally adjustable by a user through a user interface disposed at the watt hour meter.

Optionally, the unit time is any one of one minute, two minutes, three minutes, four minutes, five minutes, six minutes, ten minutes, 12 minutes, 15 minutes, 20 minutes, 30 minutes, one hour and one day.

Optionally, the unit time-based power information includes forward direction power information supplied to a load during relevant unit time.

Optionally, the forward direction power information includes one or more of effective power, ineffective power, apparent power, current amount and voltage amount.

Optionally, the time-based electric price information includes one or more of effective power unit price (won/kwh), ineffective power unit price (won/kvarh), apparent power unit price (won/kVAh), current amount unit price (won/kl²h) and voltage unit price (won/KV²h), each relative to forward direction power energy, where won is Korean currency.

Optionally, the unit time-based power information includes reverse direction power information supplied from alternative energy source to power supply line during relevant unit time.

Optionally, the time-based electric price information includes power factor unit price.

Optionally, the time-based electric price information includes rate information based on TOU (Time Of Use), CPP (Critical Peak Pricing) or RTP (Real Time Pricing).

Optionally, the watt hour meter further includes function of transmitting the electric price information to other device.

Optionally, the other device includes IHD (In Home Display).

### ADVANTAGEOUS EFFECTS

According to the present disclosure, records showing energy use history of a user for each unit time are sequentially recorded, each record including time information of relevant unit time for each unit time, energy price information applied to relevant unit time and energy consumption information at the relevant unit time, whereby information on how much, when and at what price the user has used the energy can be accurately and quite obviously managed. The energy use history can be displayed by energy meter by itself, or displayed through a home display device and can be checked at any time.

Therefore, his or her energy use history can be easily checked out without recourse to collecting energy pricing information tables or checking energy consumption for each time zone and energy pricing information tables one by one in order to find out his or her energy use history.

Once details on their energy use history are easily checked out by users, the users can adjust energy consumption more positively to save energy, thereby living up to current trend heading for reasonable energy consumption.

Furthermore, as the energy use history includes energy consumption information for each unit time and energy pricing information on relevant time, the energy use history may be advantageously utilized as a base for calculating energy use charge. In a non-limiting example, an energy supply company may use an energy use history managed by the energy meter to settle energy use charge, and use the energy use history as back-up information for charging.

In addition, the energy use history may be advantageously utilized as an important evidential data in case an energy use charge conflicts with users occur.

### BRIEF DESCRIPTION OF THE DRAWINGS

Accompanying drawings are included to provide a further understanding of arrangements and embodiments of the present disclosure and are incorporated in and constitute a part of this application. Now, non-limiting and non-exhaustive exemplary embodiments of the disclosure are described with reference to the following drawings, in which:

FIG. 1 is a schematic view illustrating an energy metering system according to an exemplary embodiment of the present disclosure;

FIG. 2 illustrates various examples of energy pricing structures that change in time;

FIG. 3 illustrates an example of record structure recording energy use history;

FIGS. 4 and 5 illustrate examples of a structure recording and managing an energy use history in storage means

FIG. 6 is an energy metering method according to exemplary embodiments of the present disclosure;

FIG. 7 is a watt hour meter according to an exemplary embodiment of the present disclosure;

FIG. 8 is a watt hour meter according to another exemplary embodiment of the present disclosure;

FIG. 9 is an example in which a current electric price is displayed on a screen.

FIG. 10 is an example in which an energy use history is displayed on a screen; and

FIG. 11 is an example illustrating forward power and reverse power.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the method particularly pointed out in the written description and claims hereof as well as the appended drawings.

### DETAILED DESCRIPTION

Hereinafter, exemplary embodiments of the present disclosure are described in detail with reference to the accompanying drawings. It will be appreciated that for simplicity and/or clarity of illustration, elements illustrated in the figure have not necessarily been drawn to scale. For example, the dimensions of some of the elements may be exaggerated relative to other elements for clarity. Further, if considered appropriate, reference numerals have been repeated among the figures to indicate corresponding and/or analogous elements.

Particular terms may be defined to describe the disclosure in the best mode as known by the inventors. Accordingly, the meaning of specific terms or words used in the specification and the claims should not be limited to the literal or commonly employed sense, but should be construed in accordance with the spirit and scope of the disclosure. The definitions of these terms therefore may be determined based on the contents throughout the specification.

In the following detailed description, numerous specific details are set forth to provide a thorough understanding of claimed subject matter. However, it will be understood by those skilled in the art that claimed subject matter may be practiced without these specific details. In other instances, well-known methods, procedures, components and/or circuits have not been described in detail.

In the following description and/or claims, the terms coupled and/or connected, along with their derivatives, may be used. In particular embodiments, connected may be used to indicate that two or more elements are in direct physical and/or electrical contact with each other. Coupled may mean that two or more elements are in direct physical and/or electrical contact. However, coupled may also mean that two or more elements may not be in direct contact with each other, but yet may still cooperate and/or interact with each other. For example, “coupled”, and “connected” may mean that two or more elements do not contact each other but are indirectly joined together via another element or intermediate elements.

Furthermore, the term “and/or” may mean “and”, it may mean “or”, it may mean “exclusive-or”, it may mean “one”, it may mean “some, but not all”, it may mean “neither”, and/or it may mean “both”, although the scope of claimed subject matter is not limited in this respect.

In the following description and/or claims, the terms “comprise” and “include,” along with their derivatives, may be used and are intended as synonyms for each other. Furthermore, the terms “including”, “includes”, “having”, “has”, “with”, or variants thereof are used in the detailed description and/or the claims to denote non-exhaustive inclusion in a manner similar to the term “comprising”.

Words such as “thereafter,” “then,” “next,” etc. are not intended to limit the order of the processes; these words are simply used to guide the reader through the description of the methods. The terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item.

In describing the present disclosure, detailed descriptions of constructions or processes known in the art may be omitted to avoid obscuring appreciation of the invention by a person of ordinary skill in the art with unnecessary detail regarding such known constructions and functions.

Now, exemplary embodiments of the present disclosure will be described in detail with reference to the accompanying drawings.

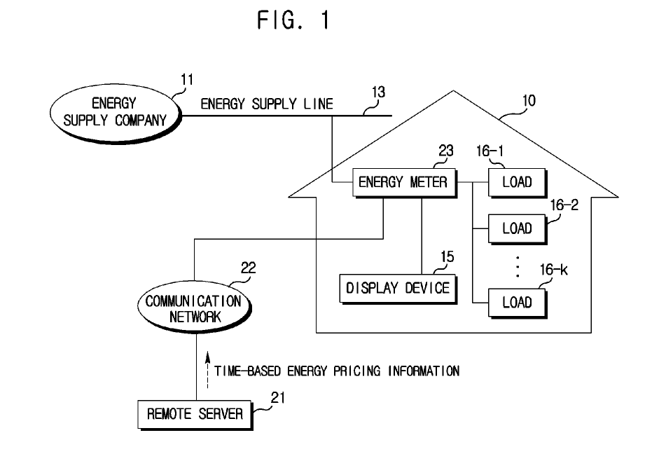

Referring to FIG. 1, energy supplied by an energy supply company (11) is transmitted to each consumer (10) through an energy supply line (13), where the consumer (10) uses the energy supplied through the energy supply line (13). The term of “energy” in the present disclosure includes any one of gas, electricity and water, unless specified otherwise.

An energy metering system according to the present disclosure includes a remote server and an energy meter (23) installed at each consumer, where the remote server and the energy meter communicate through various wireless/wired communication networks (22) and exchange information related to various energies.

The remote server (21), which is a server performing a function related to energy supply services provided by the energy supply company (11), transmits time-based energy pricing information to the energy meter (23) through the communication network (22). Energy pricing structure is subject to change based on TOU (Time Of Use) pricing, CPP (Critical Peak Pricing) and RTP (Real-Time Pricing) system.

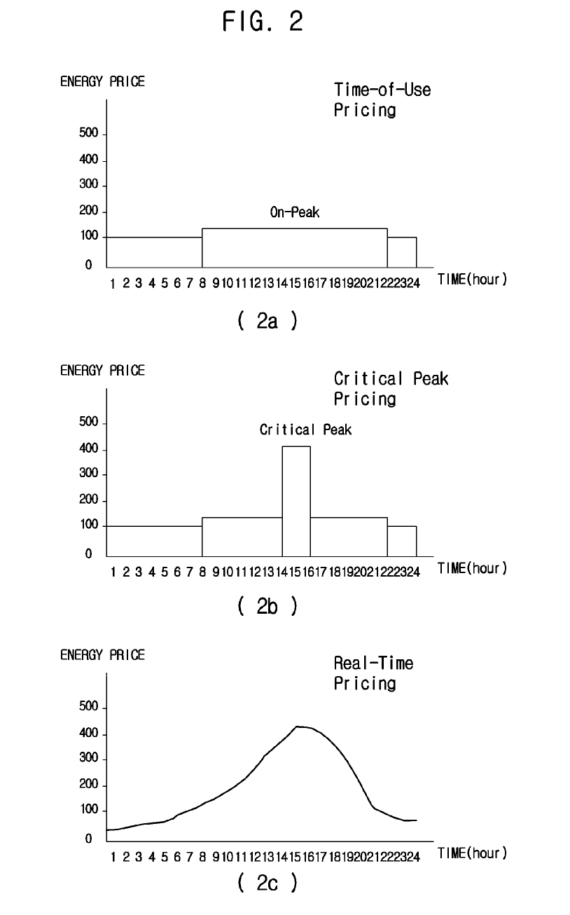

FIG. 2a illustrates a TOU system mainly used in factories, shopping districts and large buildings and shows that energy prices change in time. FIG. 2b illustrates a CPP system, showing that energy prices change in time, with highest price at a peak section. FIG. 2c illustrates a RTP system where energy prices change in real time. These energy pricing structures may be variably and unlimitedly configured in consideration of energy supply and consumption patterns.

The communication network (22) communicating with the remote server (21) and the energy meter (23) may include various communication networks. In a non-limiting example, the communication network (22) may include a power line communication network, an Internet network, a CDMA (Code Division Multiple Access) network, a PCS (Personal Communication Service) network, a PHS (Personal Handyphone System) network and a Wibro (Wireless Broadband Internet) network.

The energy consumer (10) is present with various loads (16-1 16-k) consuming the energy transmitted through the energy supply line (13). The energy meter (23) may a watt hour meter, a gas meter or a water meter. Basically, the energy meter (23) serves to measure energy consumption consumed by each load (16-1 16-k). The energy meter (23) may be variably configured based on types of energies and required functions. The energy meter (23) receives the energy pricing information based on time transmitted by the remote server (21) through the communication network (22), and operates using the information.

Particularly, the energy meter (23) records and manages an energy use (consumption) history of energy consumer (10), where the energy use history is information on how much, when and at what price a user (consumer) has used the energy, and is recorded and managed in the form of information by unit time, and where unit time may be arbitrarily set up. To be more specific, the unit time may be set up in any one of one minute, two minutes, three minutes, four minutes, five minutes, six minutes, ten minutes, 12 minutes, 15 minutes, 20 minutes, 30 minutes, one hour and one day.

The types of information manageable by the energy use history may be variable, and in the present disclosure, the energy use history includes at least time information of relevant unit time, energy pricing information applied to the relevant unit time and energy consumption information at the relevant unit time.

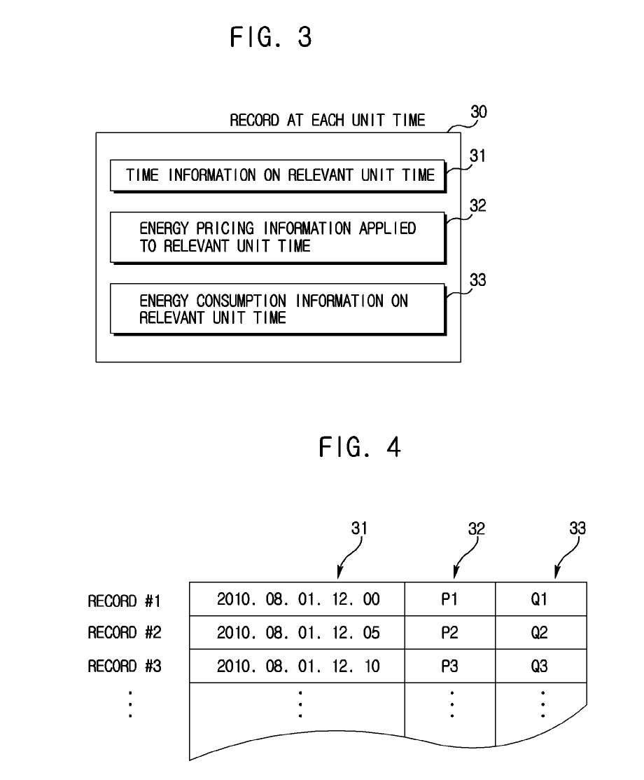

Referring to FIGS. 3, 4 and 5, an energy metering method in which the energy meter (23) records and manages the energy use history will be described in detail.

Referring to FIG. 3, each record (30) of the energy use history includes, as mentioned above, a field (31) recording at least time information of relevant unit time, a field (32) recording energy pricing information applied to the relevant unit time and a field (33) recording energy consumption information at the relevant unit time.

The term of “time information of relevant unit time” means information capable of notifying the duration of the unit time, the term of “energy pricing information applied to the relevant unit time” means information capable of energy price at the relevant unit time, where the energy meter (23) extracts the energy pricing information of the relevant unit time from the energy pricing information based on time received from the remote server (21). The term of “energy consumption information at the relevant unit time” means energy consumption used by each load during the relevant unit time.

Referring to FIG. 4, the energy meter (23) time-sequentially records a record corresponding to each unit time in the order of time in storage means, where the storage means is a non-volatile storage medium capable of reading and writing digital data for storing and maintaining various pieces of information necessary for operation of the energy meter (23).

A unit time is imagined to be five minute in FIG. 4. The record #1 is recorded with information that an energy as much as Q1 has been used at a P1 energy price at a relevant unit time, a record #2 is recorded with information that an energy as much as Q2 has been used at a P2 energy price at a relevant unit time, and a record #3 is recorded with information that an energy as much as Q3 has been used at a P3 energy price at a relevant unit time.

Although a time information field (31) of relevant unit time is recorded with a start time of each unit time as ‘year/month/day/time/minute’, it should be apparent that a start time and a finish time of each unit time can be all recorded.

The time information of relevant unit time recorded in the first field (31) may be arbitrary information capable of grasping the relevant record in relation to unit time (duration of the unit time). The energy consumption information of relevant unit time recorded in the third field (33) may be energy consumption per unit time, but may be accumulated energy consumption information. This is because the energy consumption per unit time can be known if a prior unit time value is deducted from a current unit time value, even if the accumulated energy consumption is recorded.

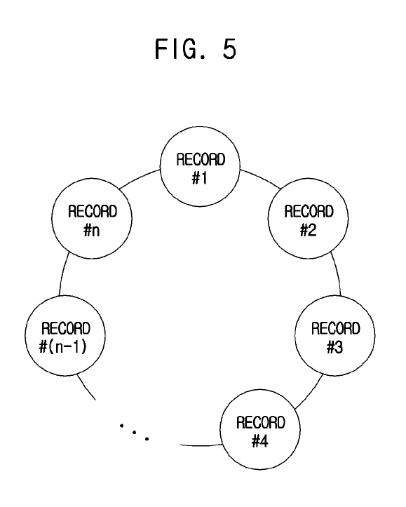

FIG. 5 illustrates an example of maintaining each record in ring structure.

If the ring structure is filled from record #1 to record #n, a record relative to next unit time maintains the energy use history in a method of recording the energy consumption information in the oldest record. In a non-limiting example, the energy use history corresponding to each unit time is sequentially recorded in from record #1 to record #n, and ‘n+1’th record is recorded in the record #1. The management of energy use history thus described is advantageous in that it is not restricted by storage capacity of the storage means, and the latest nth record can be maintained at all times.

The energy meter (23) may display the energy use history information maintained in storage means on an intrinsic screen or may provide a user interface capable of checking, by a user, the energy use history stored in the storage means. Furthermore, the energy meter (23) may transmit the energy use history recorded in the storage means to other devices (15) through various wired/wireless communication methods.

The other device (15) defines a display device capable of visually displaying the energy use history by receiving from the energy meter (23). In a non-limiting example, the other device may include an IHD (In Home Display) installed in the energy consumer (10) capable of displaying various energy-related information and a user mobile phone.

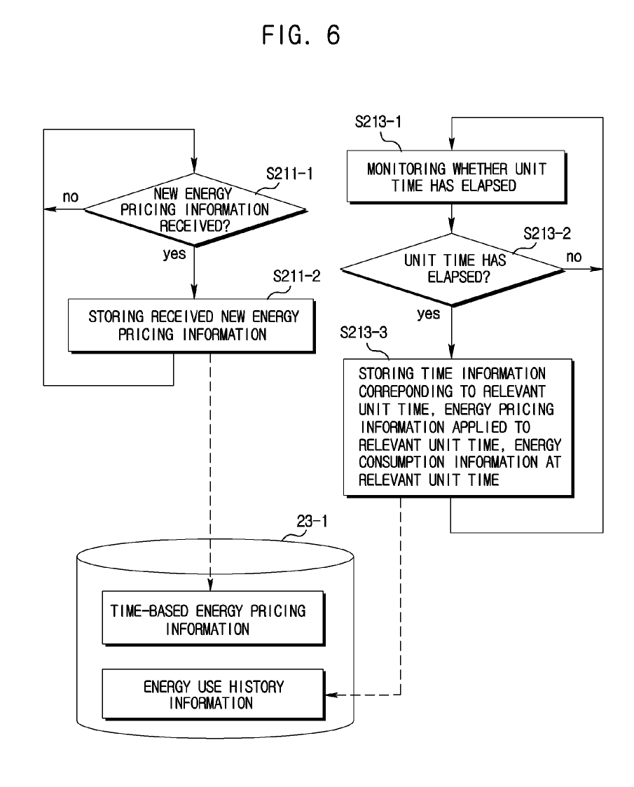

FIG. 6 is a schematic view illustrating an energy metering method according to an exemplary embodiment of the present disclosure, whereby an energy meter supporting dynamic time-varying energy pricing can manage an energy use history. The energy meter may include a watt hour meter, a gas meter and a water meter installed at each energy consumer, and is capable of communicating with a remote server through a communication network.

The energy meter basically measures energy consumption, e.g., an accumulated energy consumption consumed by each relevant energy consumer. In case the energy meter receives time-based energy pricing information from a remote server through a communication network (S211-1), the energy meter stores the received time-based energy pricing information in storage means (23-1) (S211-2).

Meanwhile, the energy meter keeps monitoring whether a preset unit time has elapsed while measuring energy consumption used by the energy consumer (S213-1). The monitoring whether the preset unit time has elapsed at step S213-1 is intended to manage the energy use history for each unit time. The unit time may be arbitrarily set up as necessary, and in a non-limiting example, the unit time may be set up at one minute, two minutes, three minutes, four minutes, five minutes, six minutes, ten minutes, 12 minutes, 15 minutes, 20 minutes, 30 minutes, one hour and one day.

As a result of the monitoring at step S213-1, if the unit time has elapsed (S213-2), the energy meter records time information of relevant unit time, energy pricing information applied to the relevant unit time and energy consumption information at the relevant unit time in storage means (23-1) (S213-3), where the time information on relevant unit time means information capable of notifying duration of the unit time, the energy pricing information applied to the relevant unit time means capable of notifying how much the energy price at the relevant unit time, which can be extracted from the time-based energy pricing information received from the remote server, and the energy consumption information at the relevant unit time means energy consumption used by each load during the relevant unit time.

The energy meter at step S213-3 time-sequentially records a record corresponding to each unit time as described in FIGS. 3, 4 and 5. The process of the energy meter receiving the energy pricing information from the remote server through steps S211-1 and S211-2, and the process of time-sequentially storing and managing the energy use history for each unit time through steps S213-1, S213-2 and S213-3 are processes that can be implemented in parallel. That is, the time-based energy pricing information may be updated by the remote server at any time when the need arises.

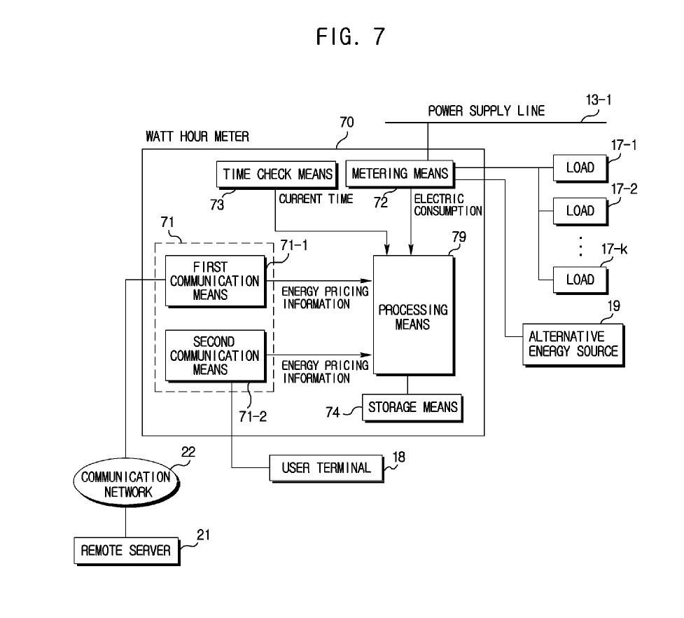

FIG. 7 is a schematic view illustrating a watt hour meter (70) according to a first exemplary embodiment of the present disclosure, where the watt hour meter (70) may include communication means (71), metering means (72), time check means (73), storage means (74) and processing means (79).

Each load (17-1˜17-k) at the power consumer consumes electric energy supplied through the power supply line (13-1), where the metering means (72) measures power consumption (e.g., accumulated power consumption) consumed by each load (17-1˜17-k) of the power consumer.

The communication means (71) functions to receive time-based electric power pricing information transmitted from the remote server or a user terminal (18). First communication means (71-1) receives time-based electric power pricing information from the remote server (21) through the communication network (22), and second communication means (71-2) receives time-based electric power pricing information from the user terminal (18). The second communication means (71-2) may communicate with the user terminal (18) using various wired/wireless communication methods.

The first and second communication means (71-1, 71-2) may be integrally realized based on the communication network (22) communicating with the remote server (21) by the first communication means (71-1) and types of networks communicating with the user terminal (18) by the second communication means (71-2).

The types of user terminal (18) may be variably provided. In a non-limiting example, the user terminal may be an IHD (In Home Display) installed in the energy consumer (10) capable of displaying various energy-related information, or a user mobile phone.

Furthermore, the processing means (79) may transmit to the user terminal (18) through the second communication means (71-2) information such as current electric power pricing information and the energy use history, and in this case, the user terminal (18) may visually display the information received from the watt hour meter (70). That is, the user terminal (18) may transmit necessary information to the watt hour meter (70) through various wired/wireless communication methods, and may receive various pieces of energy-related information from the watt hour meter (70) and display the information.

The time-based electric power pricing information received through the communication means (71) may include, as shown in FIG. 2, various tariff system-based tariff information such as TOU (Time Of Use) pricing, CPP (Critical Peak Pricing) and RTP (Real-Time Pricing).

The time check means (73) serving to measure a current time may be formed by using a RTC (Real Time Clock). The current time measured by the time check means (73) may be adjustable to correct a time measurement error. At this time, the current time may be adjusted by communication with other devices. In a non-limiting example, the remote server (21) or the user terminal (18) may transmit a time adjustment instruction, and the processing means (79) may adjust the current time of the time check means (73) in response to the received time adjustment instruction.

Furthermore, the watt hour meter (70) may include a key having a function of displaying the current time and capable of adjusting the current time. In this case, the current time on the watt hour meter (70) may be personally adjusted by the user.

The storage means (74) is non-volatile digital data storage medium recording electric power consumption information measured by the metering means (72) and operation information of the watt hour meter.

The processing means (79) may be formed by using a microprocessor or a CPU (Central Processing Unit), and processes dynamically varying electric prices that change in time.

Particularly, with reference to the present disclosure, the processing means (79) receives electric power pricing information through the communication means (71), stores in the storage means (74) the electric power consumption information measured by the metering means (72) and manages the information, and extracts electric power pricing information applied to current time, from the time-based electric power pricing information.

Furthermore, the processing means (79) uses the current time information measured by the time check means (73) to monitor whether the preset unit time has elapsed, and stores the energy use history for each unit time in the storage means (74).

Although the energy use history stored in the storage means (74) by the processing means (74) at every unit time may be variably configured as need arises, the energy use history includes at least time information of relevant unit time, electric power pricing information applied to the relevant unit time and electric power consumption information at the relevant unit time.

The unit time may be arbitrarily set up. To be more specific, the unit time may be set up in any one of one minute, two minutes, three minutes, four minutes, five minutes, six minutes, ten minutes, 12 minutes, 15 minutes, 20 minutes, 30 minutes, one hour and one day.

At this time, the time information of relevant unit time is information notifying duration of the unit time, the electric power pricing information applied to the relevant unit time is information notifying electric power prices at the relevant unit time, and the electric power consumption information at the relevant unit time means electric power consumption used during the relevant unit time.

As illustrated in FIG. 3, the energy use history for each unit time may be stored by record unit, where each record may include time information field of relevant unit time, electric pricing information field applied to the relevant unit time and electric power consumption information field at the relevant unit time. The records at each unit time may be time-sequentially recorded as shown in FIGS. 4 and 5.

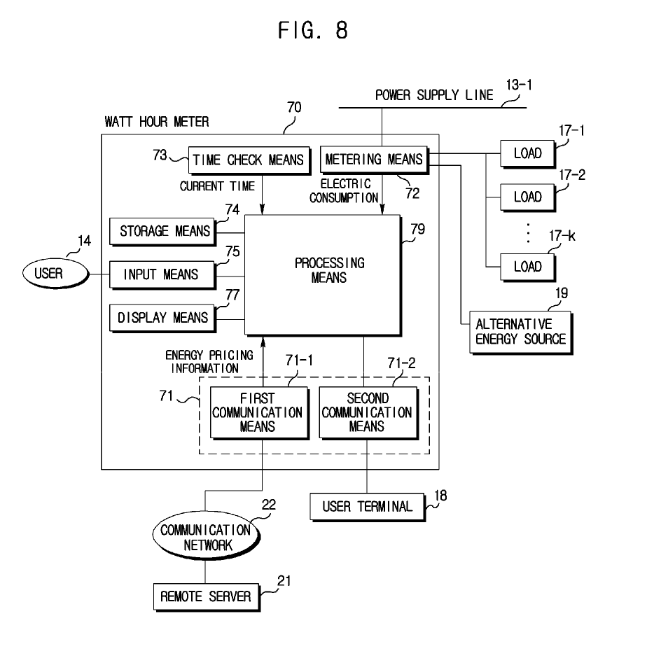

FIG. 8 is a schematic view illustrating a watt hour meter (70) according to a second exemplary embodiment of the present disclosure, where the watt hour meter (70) may further include input means (75) and display means (77) in addition to the watt hour meter according to the first exemplary embodiment of the present disclosure, and where either one of the input means (75) or display means (77), or all the input means (75) or display means (77) may be included in the watt hour meter according to the second exemplary embodiment of the present disclosure.

The display means (77) serves to visually display information related to operation of the watt hour meter (70). Particularly, the processing means (79) may variably display on the display means (77) various pieces of information related to the electric power prices including electric power pricing information applied to the current time and the energy use history.

As one example, the electric power price information applied to the current time may be displayed at all times or intermittently. Furthermore, the electric power price information applied to the current time may be periodically displayed. In a non-limiting example, current electric power pricing information at each unit time may be displayed. The processing means (79) may extract electric pricing information scheduled at a future time from the time-based electric power pricing information, and display the information on the display means (77).

The input means (75) may input information or instruction related to operation of watt hour meter (70) using various input devices, by a user, including a key button and a touch screen.

In a non-limiting example, the time-based electric power pricing information may be publicized through an Internet network, where the user may personally input the time-based electric power pricing information through the input means (75). Furthermore, if there is an error in the current time measured by the time check means (73), the current time information may be adjusted through the input means (75).

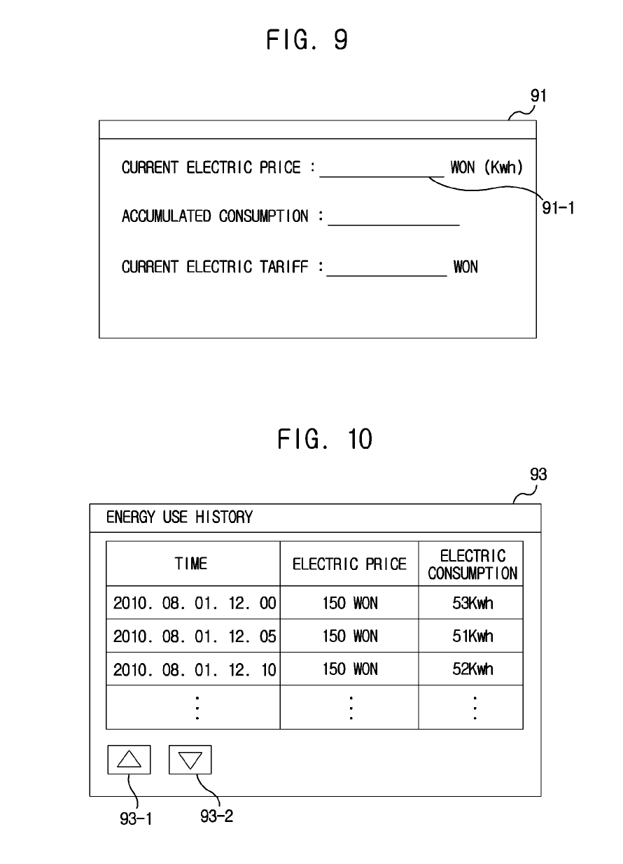

FIG. 9 is a schematic view illustrating an example of a screen (91) displaying a current electric price displayed by the display means (77) or the user terminal (18), where the current electric price extracted from the time-based electric pricing information is displayed on a relevant item (91-1).

FIG. 10 is a schematic view illustrating an example of a screen (93) displaying an energy use history, where the screen displays time information at each unit time, electric pricing information applied to the relevant unit time and electric power consumption information for each unit time. The user may manipulate scroll buttons (93-1, 93-2) to check each energy use history not shown on the current screen.

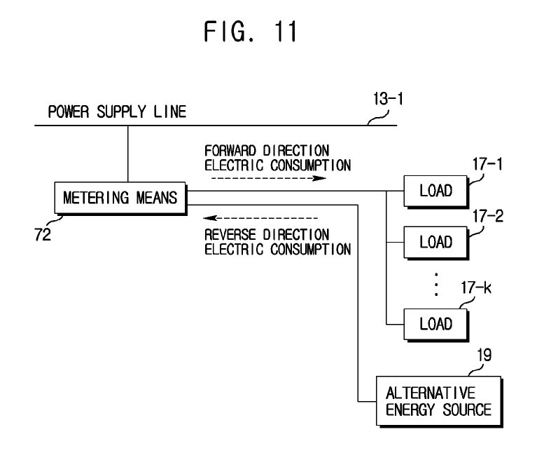

Meantime, the electric power consumption information at each unit time may be forward direction electric power consumption information supplied to the loads (17-1˜17-k) during relevant unit time, as shown in FIG. 11. The forward direction electric power consumption means electric power quantity (i.e., electric power consumption to be paid as an electric power charge) used by an electric power consumer.

The forward direction power information includes effective power, ineffective power, apparent power, current amount and voltage amount. At this time, the time-based electric price information includes effective power unit price (won/kwh), ineffective power unit price (won/kvarh), apparent power unit price (won/kVAh), current amount unit price (won/kl²h) and voltage unit price (won/KV²h), where won is Korean currency, each relative to information on forward direction power energy, and the electric pricing information may include a power factor unit price.

That is, if power factor is bad, waste of electric energy becomes serious, such that the electric power price can be differentiated in response to power factor of electric power consumer.

The electric power information at each unit time may also include information on reverse direction electric power supplied to the power supply line (13-1) from an alternative energy source (19) during a relevant unit time as shown in FIG. 11. The reverse direction electric power means electric power sold by electric power consumers to a power supply company.

Each electric power consumer may be equipped with various alternative energy sources such as wind power generating facilities, solar power generating facilities and batteries, and the electric energy generated by the alternative energy source (19) may be re-sold to the electric power company. The reverse direction electric power may include effective power, ineffective power, apparent power, current amount and voltage amount.

At this time, the electric price information includes effective power unit price (won/kwh), ineffective power unit price (won/kvarh), apparent power unit price (won/kVAh), current amount unit price (won/kl²h) and voltage unit price (won/KV²h), each relative to information on reverse direction power energy, where won is Korean currency.

The price of electricity sold by the power supply company to the electric power consumer, and the price of electricity sold by the electric power consumer to the power supply company may be differentiated, such that the electric price on forward direction electric consumption and the electric price on reverse direction electric consumption may be dissimilar.

The energy metering system and the energy metering method and the watt hour meter of supporting dynamic time-varying energy pricing according to the present disclosure may, however, be embodied in many different forms and should not be construed as limited to the embodiments set forth herein. Thus, it is intended that embodiments of the present disclosure may cover the modifications and variations of this disclosure provided they come within the scope of the appended claims and their equivalents.

While particular features or aspects may have been disclosed with respect to several embodiments, such features or aspects may be selectively combined with one or more other features and/or aspects of other embodiments as may be desired.

What is claimed is:

1. An energy metering system supporting dynamic time-varying energy pricing, the system comprising: a remote server managing the dynamic time-varying energy pricing system where energy price changes in time; a communication network connecting the remote server and an energy meter; and the energy meter measuring energy consumption flowing via the energy metering system, and receiving time-based energy price information from the communication network, wherein the energy meter extracts current time-applied energy price information from the time-based energy price information, and time-sequentially records in storage means
a record including time information of relevant unit time for each unit time, the extracted energy price information and energy consumption information at relevant unit time.

2. An energy metering method supporting dynamic time-varying energy pricing system, the method comprising: receiving, by an energy meter, time-based energy price information from a remote server through a communication network; measuring, by the energy meter, energy consumption and monitoring whether a pre-set unit time has elapsed; and time-sequentially recording in storage means, by the energy meter, a record including time information of relevant unit time for each unit time, energy price information applied to relevant unit time and energy consumption information at the relevant unit time.

3. The method of claim 2, wherein the energy meter measures any one of electricity, gas and water consumption.

4. The method of claim 2, wherein the unit time is any one of one minute, two minutes, three minutes, four minutes, five minutes, six minutes, ten minutes, 12 minutes, 15 minutes, 20 minutes, 30 minutes, one hour and one day.

5. A watt hour meter supporting dynamic time-varying energy pricing system, the meter comprising: communication means receiving time-based electric price information from a remote server or a user; metering means measuring power consumption flowing through the watt hour meter; storage means recording the measured power consumption and operation information of the watt hour meter; time check means measuring a current time; and processing means processing the watt hour meter in which electric price is dynamically changed in time, wherein the processing means extracts current time-applied electric price information from time-based electric price information received from the communication means, and time-sequentially records in storage means a record including time information of relevant unit time for each unit time, the extracted electric price information and power consumption information at relevant unit time.

6. The watt hour meter of claim 5, further comprising display means capable of displaying electric price information.

7. The watt hour meter of claim 6, wherein the display means displays the current time-applied electric price information at all times or intermittently.

8. The watt hour meter of claim 6, wherein the display means periodically displays the current time-applied electric price information.

9. The watt hour meter of claim 6, wherein the processing means displays future time-scheduled electric price information through the display means.

10. The watt hour meter of claim 5, wherein the current time measured by the time check means is adjustable.

11. The watt hour meter of claim 10, wherein the current time is adjustable by communication with other devices, or personally adjustable by a user through a user interface disposed at the watt hour meter.

12. The watt hour meter of claim 5, wherein the unit time is any one of one minute, two minutes, three minutes, four minutes, five minutes, six minutes, ten minutes, 12 minutes, 15 minutes, 20 minutes, 30 minutes, one hour and one day.

13. The watt hour meter of claim 5, wherein the unit time-based power information includes forward direction power information supplied to a load during relevant unit time.

14. The watt hour meter of claim 13, wherein the forward direction power information includes one or more of effective power, ineffective power, apparent power, current amount and voltage amount.

15. The watt hour meter of claim 14, wherein the time-based electric price information includes one or more of effective power unit price (won/kwh), ineffective power unit price (won/kvarh), apparent power unit price (won/kVAh), current amount unit price (won/kl²h) and voltage unit price (won/KV²h), each relative to forward direction power energy, where won is Korean currency.

16. The watt hour meter of claim 5, wherein the unit time-based power information includes reverse direction power information supplied from alternative energy source to power supply line during relevant unit time.

17. The watt hour meter of claim 5, wherein the time-based electric price information includes power factor unit price.

18. The watt hour meter of claim 5, wherein the time-based electric price information includes rate information based on TOU (Time Of Use), CPP (Critical Peak Pricing) or RTP (Real Time Pricing).

19. The watt hour meter of claim 5, wherein the watt hour meter further includes function of transmitting the electric price information to other device.

20. The watt hour meter of claim 19, wherein the other device includes IHD (In Home Display).
